(19) United States
(12) Patent Application Publication
(10) Pub. No.: US 2022/0270976 A1
(43) Pub. Date: Aug. 25, 2022

(54) MICROELECTRONIC ASSEMBLIES INCLUDING BRIDGES

(71) Applicants: Xiaoxuan Sun, Phoenix, AZ (US); Purushotham Kaushik Muthur Srinath, Chandler, AZ (US); Sairam Agraharam, Chandler, AZ (US)

(72) Inventors: Xiaoxuan Sun, Phoenix, AZ (US); Purushotham Kaushik Muthur Srinath, Chandler, AZ (US); Sairam Agraharam, Chandler, AZ (US)

(21) Appl. No.: 17/183,132

(22) Filed: Feb. 23, 2021

(51) Int. Cl. H01L 23/538; H01L 25/065; H01L 23/00

(52) U.S. Cl. CPC H01L 23/5386; H01L 25/0655; H01L 23/5385; H01L 24/16; H01L 23/5383; H01L 24/14; H01L 2224/16227; H01L 2224/14177

(57) ABSTRACT

Disclosed herein are microelectronic assemblies including bridges, as well as related methods. In some embodiments, a microelectronic assembly may include a bridge in a mold material.

### BACKGROUND

In conventional microelectronic packages, a die may be attached to an organic package substrate by solder. Such a package may be limited in the achievable interconnect density between the package substrate and the die, the achievable speed of signal transfer, and the achievable miniaturization, for example.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of an example microelectronic structure, in accordance with various embodiments.

FIG. 2 is a side, cross-sectional view of an example microelectronic assembly including the microelectronic structure of FIG. 1, in accordance with various embodiments.

FIGS. 3-10 are side, cross-sectional views of various stages in an example process for the manufacture of the microelectronic assembly of FIG. 2, in accordance with various embodiments.

FIG. 11 is a side, cross-sectional view of an example microelectronic structure, in accordance with various embodiments.

FIG. 12 is a side, cross-sectional, exploded view of an example microelectronic assembly, in accordance with various embodiments.

FIGS. 13-16 are side, cross-sectional views of example microelectronic assemblies, in accordance with various embodiments.

FIGS. 17-26 are side, cross-sectional views of various stages in an example process for the manufacture of the microelectronic assembly of FIG. 13, in accordance with various embodiments.

FIGS. 27-28 are side, cross-sectional views of example microelectronic assemblies, in accordance with various embodiments.

FIGS. 29-33 are side, cross-sectional views of various stages in an example process for the manufacture of the microelectronic assembly of FIG. 13, in accordance with various embodiments.

FIGS. 34-35 are side, cross-sectional views of various stages in alternate example processes for the manufacture of the microelectronic assembly of FIG. 13 and other microelectronic assemblies, in accordance with various embodiments.

FIG. 36 is a side, cross-sectional view of an example microelectronic assembly, in accordance with various embodiments.

FIG. 37 is a side, cross-sectional, exploded view of an example microelectronic assembly, in accordance with various embodiments.

FIG. 38 is a top view of a wafer and dies that may be included in a microelectronic structure or microelectronic assembly in accordance with any of the embodiments disclosed herein.

FIG. 39 is a side, cross-sectional view of an integrated circuit (IC) device that may include be included in a microelectronic structure or microelectronic assembly in accordance with any of the embodiments disclosed herein.

FIG. 40 is a side, cross-sectional view of an IC device assembly that may include a microelectronic structure or microelectronic assembly in accordance with any of the embodiments disclosed herein.

FIG. 41 is a block diagram of an example electrical device that may include a microelectronic structure or microelectronic assembly in accordance with any of the embodiments disclosed herein.

### DETAILED DESCRIPTION

Disclosed herein are microelectronic assemblies including bridges, as well as related methods. In some embodiments, a microelectronic assembly may include a bridge in a mold material. Various ones of the embodiments disclosed herein may achieve a patch structure with protruded conductive contacts that enable continued pitch reduction with high reliability and low manufacturing complexity. Further, various ones of the embodiments disclosed herein may achieve reduced mold material thickness relative to some previous approaches, improving warpage control.

To achieve high interconnect density in a microelectronics package, some conventional approaches require costly manufacturing operations, such as fine-pitch via formation and first-level interconnect plating in substrate layers over an embedded bridge, done at panel scale. The microelectronic structures and assemblies disclosed herein may achieve interconnect densities as high or higher than conventional approaches without the expense of conventional costly manufacturing operations. Further, the microelectronic structures and assemblies disclosed herein offer new flexibility to electronics designers and manufacturers, allowing them to select an architecture that achieves their device goals without excess cost or manufacturing complexity.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The phrase “A or B” means (A), (B), or (A and B). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. When used to describe a range of dimensions, the phrase “between X and Y” represents a range that includes X and Y.

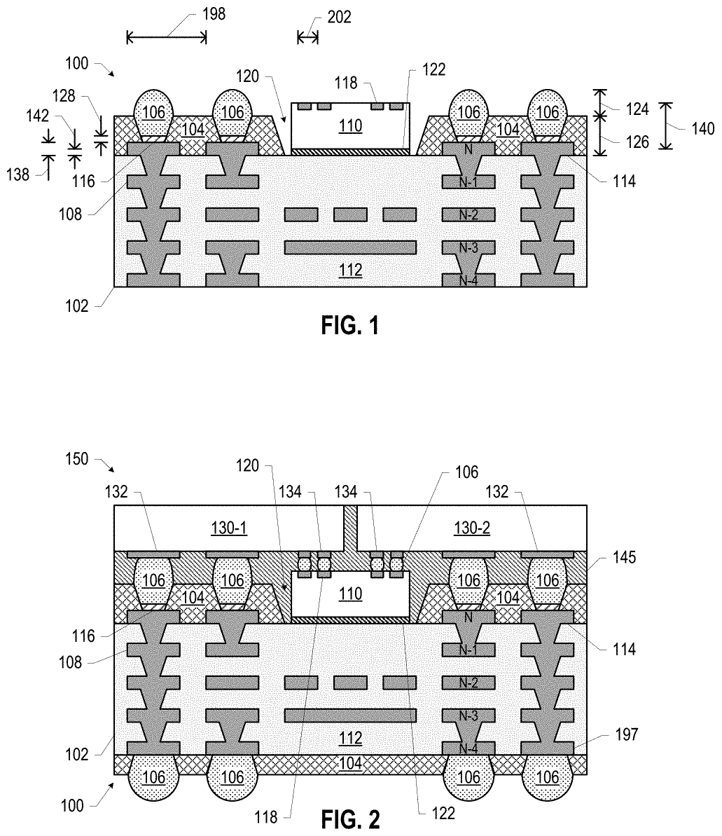

FIG. 1 is a side, cross-sectional view of an example microelectronic structure 100. The microelectronic structure 100 may include a substrate 102 and a bridge component 110 in a cavity 120 at a “top” face of the substrate 102. The substrate 102 may include a dielectric material 112 and conductive material 108, with the conductive material 108 arranged in the dielectric material 112 (e.g., in lines and vias, as shown) to provide conductive pathways through the substrate 102. In some embodiments, the dielectric material 112 may include an organic material, such as an organic buildup film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 102 may include layers of dielectric material 112/conductive material 108, with lines of conductive material 108 in one layer electrically coupled to lines of conductive material 108 in an adjacent layer by vias of the conductive material 108. A substrate 102 including such layers may be formed using a printed circuit board (PCB) fabrication technique, for example. A substrate 102 may include N such layers, where N is an integer greater than or equal to one; in the accompanying drawings, the layers are labeled in descending order from the face of the substrate 102 closest to the cavity 120 (e.g., layer N, layer N−1, layer N−2, etc.). Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. For example, although FIG. 1 and others of the accompanying drawings do not illustrate conductive material 108 in layer N−1 under the bridge component 110, conductive material 108 may be present in layer N−1 under the bridge component 110. Further, although a particular number of layers are shown in the substrate 102 (e.g., five layers), these layers may represent only a portion of the substrate 102, and further layers may be present (e.g., layers N−5, N−6, etc.).

As noted above, a microelectronic structure 100 may include a cavity 120 at the “top” face of the substrate 102. In the embodiment of FIG. 1, the cavity 120 extends through a surface insulation material 104 at the “top” face, and the bottom of the cavity is provided by the “topmost” dielectric material 112. The surface insulation material 104 may include a solder resist and/or other dielectric materials that may provide surface electrical insulation and may be compatible with solder-based or non-solder-based interconnects, as appropriate. In other embodiments, a cavity 120 in a substrate 102 may extend into the dielectric material 112, as discussed further below. The cavity 120 may have a tapered shape, as shown in FIG. 1, narrowing toward the bottom of the cavity 120. The substrate 102 may include conductive contacts 114 at the “top” face that are coupled to conductive pathways formed by the conductive material 108 through the dielectric material 112, allowing components electrically coupled to the conductive contacts 114 (not shown in FIG. 1, but discussed below with reference to FIG. 2) to couple to circuitry within the substrate 102 and/or to other components electrically coupled to the substrate 102. The conductive contacts 114 may include a surface finish 116, which may protect the underlying material of the conductive contact from corrosion. In some embodiments, the surface finish 116 may include nickel, palladium, gold, or a combination thereof. The conductive contacts 114 may be located at the “top” face and outside the cavity 120; as shown, the surface insulation material 104 may include openings at the bottom of which the surface finishes 116 of the conductive contacts 114 are exposed. Any of the conductive contacts disclosed herein may include a surface finish 116, whether or not such a surface finish 116 is expressly illustrated. In FIG. 1, solder 106 (e.g., a solder ball) may be disposed in the openings, and in conductive contact with the conductive contacts 114. As shown in FIG. 1 and others of the accompanying drawings, these openings in the surface insulation material 104 may be tapered, narrowing toward the conductive contacts 114. In some embodiments, the solder 106 on the conductive contacts 114 may be first-level interconnects, while in other embodiments, non-solder first-level interconnects may be used to electrically couple the conductive contacts 114 to another component. As used herein, a “conductive contact” may refer to a portion of conductive material (e.g., one or more metals) serving as part of an interface between different components; although some of the conductive contacts discussed herein are illustrated in a particular manner in various ones of the accompanying drawings, any conductive contacts may be recessed in, flush with, or extending away from a surface of a component, and may take any suitable form (e.g., a conductive pad or socket).

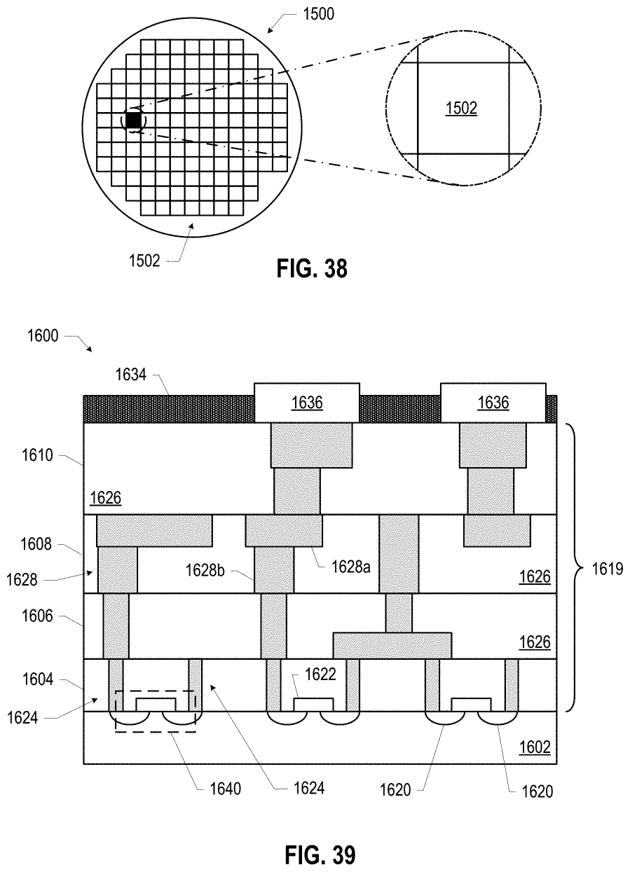

A bridge component 110 may be disposed in the cavity 120, and may be coupled to the substrate 102. This coupling may include electrical interconnects or may not include electrical interconnects; in the embodiment of FIG. 1, the bridge component 110 is mechanically coupled to the dielectric material 112 of the substrate 102 by an adhesive 122 (e.g., a die attach film (DAF)) between the “bottom” face of the bridge component 110 and the substrate 102, while other types of couplings are described elsewhere herein. The bridge component 110 may include conductive contacts 118 at its “top” face; as discussed below with reference to FIG. 2, these conductive contacts 118 may be used to electrically couple the bridge component 110 to one or more other microelectronic components. The bridge component 110 may include conductive pathways (e.g., including lines and vias, as discussed below with reference to FIG. 39) to the conductive contacts 118 (and/or to other circuitry included in the bridge component 110 and/or to other conductive contacts of the bridge component 110, as discussed below). In some embodiments, the bridge component 110 may include a semiconductor material (e.g., silicon); for example, the bridge component 110 may be a die 1502, as discussed below with reference to FIG. 38, and may include an integrated circuit (IC) device 1600, as discussed below with reference to FIG. 39. In some embodiments, the bridge component 110 may be an “active” component in that it may contain one or more active devices (e.g., transistors), while in other embodiments, the bridge component 110 may be a “passive” component in that it does not contain one or more active devices. The bridge component 110 may be manufactured so as to permit a greater density of interconnects than the substrate 102. Consequently, the pitch 202 of the conductive contacts 118 of the bridge component 110 may be less than the pitch 198 of the conductive contacts 114 of the substrate 102. When multiple microelectronic components are coupled to the bridge component 110 (e.g., as discussed below with reference to FIG. 2), these microelectronic components may use the electrical pathways through the bridge component 110 (and may use other circuitry within the bridge component 110, when present) to achieve a higher density interconnection between them, relative to interconnections made via the conductive contacts 114 of the substrate 102.

The dimensions of the elements of a microelectronic structure 100 may take any suitable values. For example, in some embodiments, the thickness 138 of the metal lines of the conductive contacts 114 may be between 5 microns and 25 microns. In some embodiments, the thickness 128 of the surface finish 116 may be between 5 microns and 10 microns (e.g., 7 microns of nickel coated with less than 100 nanometers of each of palladium and gold). In some embodiments, the thickness 142 of the adhesive 122 may be between 2 microns and 10 microns. In some embodiments, the pitch 202 of the conductive contacts 118 of the bridge component 110 may be less than 70 microns (e.g., between 25 microns and 70 microns, between 25 microns and 65 microns, between 40 microns and 70 microns, or less than 65 microns). In some embodiments, the pitch 198 of the conductive contacts 114 may be greater than 70 microns (e.g., between 90 microns and 150 microns). In some embodiments, the thickness 126 of the surface insulation material 104 may be between 25 microns and 50 microns. In some embodiments, the height 124 of the solder 106 above the surface insulation material 104 may be between 25 microns and 50 microns. In some embodiments, the thickness 140 of the bridge component 110 may be between 30 microns and 200 microns. In some embodiments, a microelectronic structure 100 may have a footprint that is less than 100 square millimeters (e.g., between 4 square millimeters and 80 square millimeters).

A microelectronic structure 100, like that of FIG. 1 and others of the accompanying drawings, may be included in a larger microelectronic assembly. FIG. 2 illustrates an example of such a microelectronic assembly 150, which may include one or more microelectronic components 130 having conductive contacts 134 coupled to the conductive contacts 118 of the bridge component 110 (e.g., by solder 106 or another interconnect structure) and conductive contacts 132 coupled to the conductive contacts 114 of the substrate 102 (e.g., by solder 106 or another interconnect structure, as discussed above). FIG. 2 illustrates two microelectronic components 130 (the microelectronic components 130-1 and 130-2), but a microelectronic assembly 150 may include more or fewer microelectronic components 130. Although FIG. 2 depicts the microelectronic components 130-1/130-2 as substantially “covering” the proximate surface of the microelectronic structure 100, this is simply an illustration, and need not be the case. Further, although FIGS. 1 and 2 (and others of the accompanying drawings) depict microelectronic structures 100/microelectronic assemblies 150 that include a single bridge component 110 in a substrate 102, this is simply for ease of illustration, and a microelectronic structure 100/microelectronic assembly 150 may include multiple bridge components 110 in a substrate 102.

The microelectronic components 130 may include conductive pathways (e.g., including lines and vias, as discussed below with reference to FIG. 39) to the conductive contacts 132/134 (and/or to other circuitry included in the microelectronic component 130 and/or to other conductive contacts of the microelectronic component 130, not shown). In some embodiments, a microelectronic component 130 may include a semiconductor material (e.g., silicon); for example, a microelectronic component 130 may be a die 1502, as discussed below with reference to FIG. 38, and may include an IC device 1600, as discussed below with reference to FIG. 39. In some embodiments, the microelectronic component 130 may be an “active” component in that it may contain one or more active devices (e.g., transistors), while in other embodiments, the microelectronic component 130 may be a “passive” component in that it does not contain one or more active devices. In some embodiments, for example, a microelectronic component 130 may be a logic die. More generally, the microelectronic components 130 may include circuitry to perform any desired functionality. For example, one or more of the microelectronic components 130 may be logic dies (e.g., silicon-based dies), and one or more of the microelectronic components 130 may be memory dies (e.g., high bandwidth memory). As discussed above with reference to FIG. 1, when multiple microelectronic components 130 are coupled to the bridge component 110 (e.g., as shown in FIG. 2), these microelectronic components 130 may use the electrical pathways through the bridge component 110 (and may use other circuitry within the bridge component 110, when present) to achieve a higher density interconnection between them, relative to interconnections made via the conductive contacts 114 of the substrate 102.

As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

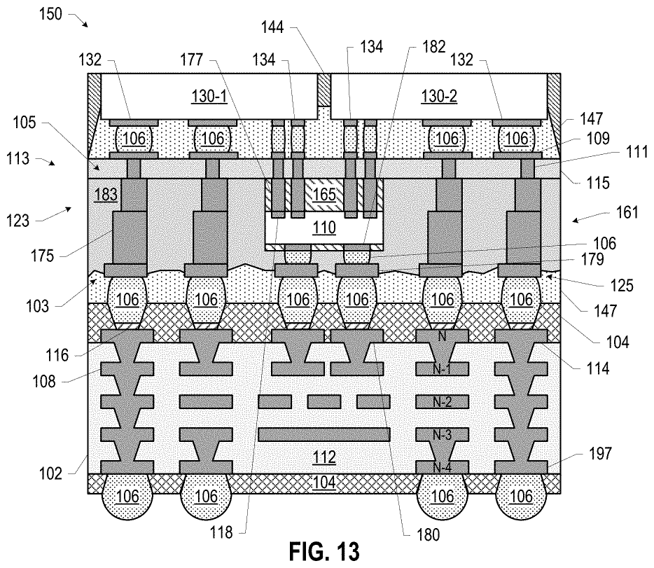

In some embodiments, a dielectric material 145 may be disposed between the microelectronic structure 100 and the microelectronic components 130, and may also be between the microelectronic components 130 and above the microelectronic components 130 (not shown). In some embodiments, the dielectric material 145 may include multiple different types of materials, including an underfill material between the microelectronic components 130 and the microelectronic structure 100 (e.g., the underfill material 147 discussed below with reference to FIG. 13) and a mold material disposed above and at side faces of the microelectronic components 130 (e.g., the mold material 144 discussed below with reference to FIG. 13). Example materials that may be used for the dielectric material 145 include epoxy materials, as suitable.

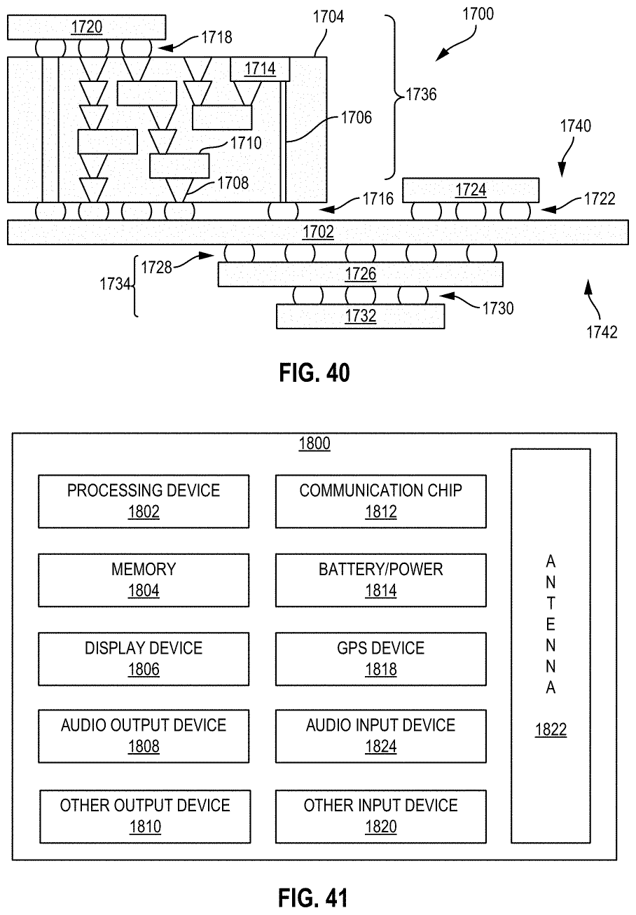

The microelectronic assembly 150 also illustrates a surface insulation material 104 at the “bottom” face of the substrate 102 (opposite to the “top” face), with tapered openings in the surface insulation material 104 at the bottoms of which conductive contacts 197 are disposed. Solder 106 may be disposed in these openings, in conductive contact with the conductive contacts 197. The conductive contacts 197 may also include a surface finish (not shown). In some embodiments, the solder 106 on the conductive contacts 197 may be second-level interconnects (e.g., solder balls for a ball grid array arrangement), while in other embodiments, non-solder second-level interconnects (e.g., a pin grid array arrangement or a land grid array arrangement) may be used to electrically couple the conductive contacts 197 to another component. The conductive contacts 197/solder 106 (or other second-level interconnects) may be used to couple the substrate 102 to another component, such as a circuit board (e.g., a motherboard), an interposer, or another IC package, as known in the art and as discussed below with reference to FIG. 40. In embodiments in which the microelectronic assembly 150 includes multiple microelectronic components 130, the microelectronic assembly 150 may be referred to as a multi-chip package (MCP). A microelectronic assembly 150 may include additional components, such as passive components (e.g., surface-mount resistors, capacitors, and inductors disposed at the “top” face or the “bottom” face of the substrate 102), active components, or other components.

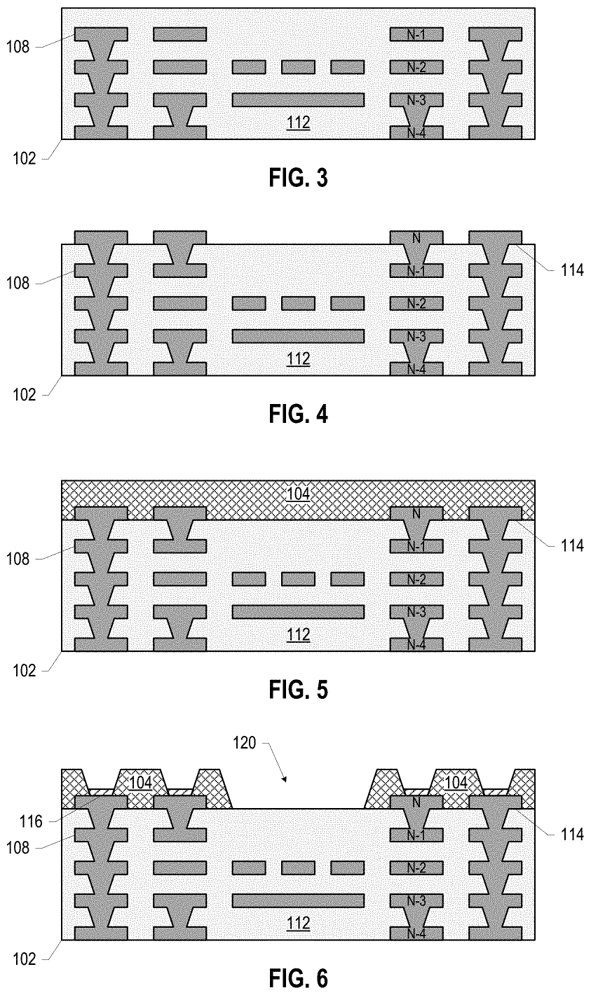

FIGS. 3-10 are side, cross-sectional views of various stages in an example process for the manufacture of the microelectronic assembly 150 of FIG. 2, in accordance with various embodiments. Although the operations of the process of FIGS. 3-10 (and the processes of others of the accompanying drawings, discussed below) may be illustrated with reference to particular embodiments of the microelectronic structures 100/microelectronic assemblies 150 disclosed herein, the method may be used to form any suitable microelectronic structures 100/microelectronic assemblies 150. Operations are illustrated once each and in a particular order in FIGS. 3-10 (and in the figures representing others of the manufacturing processes disclosed herein), but the operations may be reordered and/or repeated as desired (e.g., with different operations performed in parallel when manufacturing multiple microelectronic structures 100/microelectronic assemblies 150).

FIG. 3 illustrates an assembly that includes a preliminary substrate 102 including dielectric material 112 and patterned conductive material 108. The assembly of FIG. 3 may be manufactured using conventional package substrate manufacturing techniques (e.g., lamination of layers of the dielectric material 112, etc.), and may include layers up to N−1.

FIG. 4 illustrates an assembly subsequent to fabricating an additional Nth layer for the preliminary substrate 102 of FIG. 4. The assembly of FIG. 4 includes the underlying metal of the conductive contacts 114. The assembly of FIG. 4 may be manufactured using conventional package substrate manufacturing techniques.

FIG. 5 illustrates an assembly subsequent to former a layer of surface insulation material 104 on the assembly of FIG. 4.

FIG. 6 illustrates an assembly subsequent to patterning openings in the surface insulation material 104 of the assembly of FIG. 5 to expose the underlying metal of the conductive contacts 114, forming the surface finish 116 of the conductive contacts 114, and forming the cavity 120. In some embodiments, the openings in the surface insulation material 104 (including the cavity 120) may be formed by mechanical patterning, laser patterning, dry etch patterning, or lithographic patterning techniques.

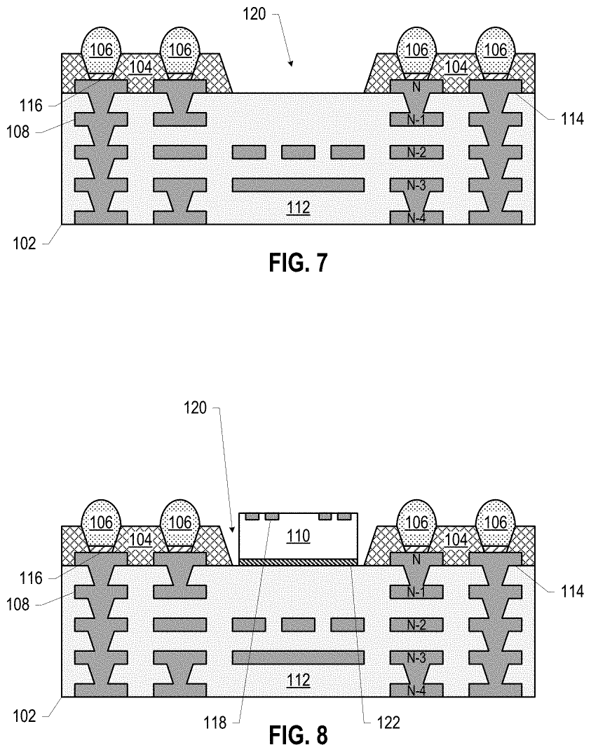

FIG. 7 illustrates an assembly subsequent to performing a cleaning operation on the assembly of FIG. 6, and forming the solder 106 (e.g., microballs) on the conductive contacts 114.

FIG. 8 illustrates an assembly subsequent to attaching the bridge component 110 to the exposed dielectric material 112 of the cavity 120 of the assembly of FIG. 7, using the adhesive 122. In some embodiments, the adhesive 122 may be a DAF, and attaching the bridge component 110 may include performing a film cure operation. The assembly of FIG. 8 may take the form of the microelectronic structure 100 of FIG. 1.

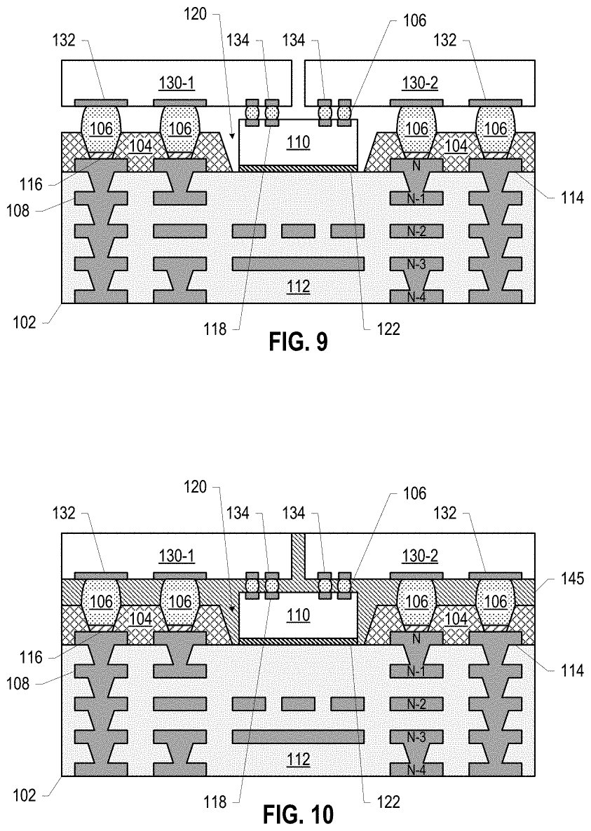

FIG. 9 illustrates an assembly subsequent to attaching the microelectronic components 130 to the assembly of FIG. 8. In some embodiments, this attachment may include a thermocompression bonding (TCB) operation. In some embodiments, additional solder may be provided on the conductive contacts 118, the conductive contacts 132, and/or the conductive contacts 134 before the TCB operation.

FIG. 10 illustrates an assembly subsequent to providing the dielectric material 145 to the assembly of FIG. 9. As noted above, in some embodiments, the dielectric material 145 of FIG. 10 may include multiple different materials (e.g., a capillary underfill material between the microelectronic components 130 and the microelectronic structure 100, and a different material over the microelectronic components 130). The assembly of FIG. 10 may take the form of the microelectronic assembly 150 of FIG. 2.

Various ones of FIGS. 1-37 illustrate example microelectronic structures 100/microelectronic assemblies 150 having various features. The features of these microelectronic structures 100/microelectronic assemblies 150 may be combined with any other features disclosed herein, as suitable, to form a microelectronic structure 100/microelectronic assembly 150. For example, any of the microelectronic structures 100 disclosed herein may be coupled to one or more microelectronic components 130 (e.g., as discussed above with reference to FIGS. 2-10) to form a microelectronic assembly 150, and any of the microelectronic assemblies 150 disclosed herein may be manufactured separately from their constituent microelectronic structures 100. A number of elements of FIGS. 1 and 2 are shared with FIGS. 3-37; for ease of discussion, a description of these elements is not repeated, and these elements may take the form of any of the embodiments disclosed herein.

A microelectronic structure 100 may include a cavity 120 that extends through a surface insulation material 104 at a “top” face of the substrate 102 (e.g., as discussed above with reference to FIG. 1). In some embodiments, the dielectric material 112 of the substrate 102 may provide the bottom of the cavity 120 (e.g., as discussed above with reference to FIG. 1), while in other embodiments, another material may provide a bottom of the cavity 120.

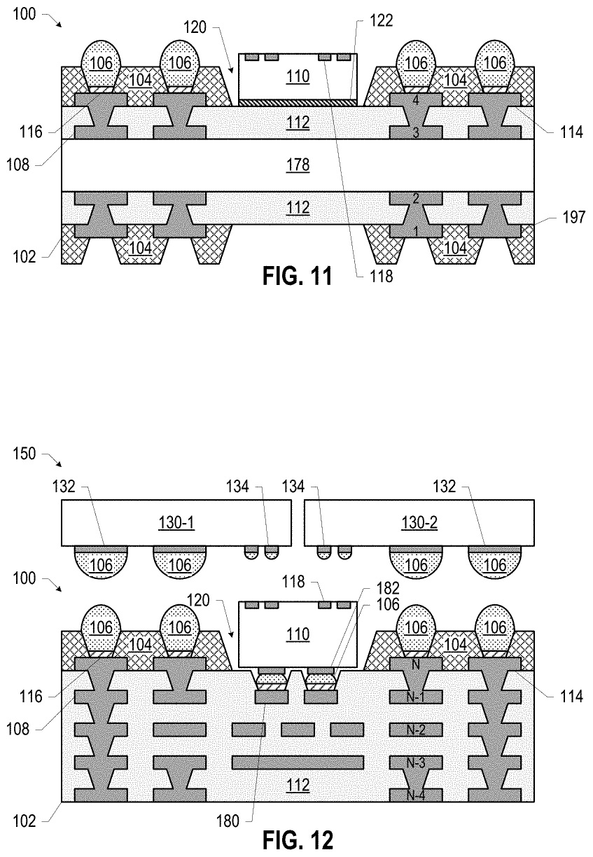

Although various ones of the drawings herein illustrate the substrate 102 as a coreless substrate (e.g., having vias that all taper in the same direction), any of the substrates 102 disclosed herein may be cored substrates 102. For example, FIG. 11 illustrates a microelectronic structure 100 having similar features to the microelectronic structure of FIG. 1, but having a substrate 102 having a core 178 (through which conductive pathways, not shown, may extend). As shown in FIG. 11, a cored substrate 102 may include vias that taper toward the core 178 (and thus taper in opposite directions at opposite sides of the core 178).

As noted above, in some embodiments, the bridge component 110 may include conductive contacts other than the conductive contacts 118 at its “top” face; for example, the bridge component 110 may include conductive contacts 182 at its “bottom” face, as shown in a number of the accompanying drawings. For example, FIG. 12 illustrates an embodiment of a microelectronic structure 100 similar to that of FIG. 1, but in which conductive contacts 182 of the bridge component 110 are coupled to conductive contacts 180 of the substrate 102 by solder 106. In a microelectronic structure 11, the conductive contacts 182 of the bridge component 110 may be conductively coupled to conductive contacts 180 at the bottom of the cavity 120 of the substrate 102 (e.g., by solder 106 or another type of interconnect). In some embodiments, the conductive contacts 180 may be at the bottom of corresponding cavities in the dielectric material 112, as shown. The conductive contacts 180 may include a surface finish 116 at their exposed surfaces, as shown. Direct electrical connections between the substrate 102 and the bridge component 110 (i.e., electrical connections that do not go through a microelectronic component 130) may enable direct power and/or input/output (I/O) pathways between the substrate 102 and the bridge component 110, which may result in power delivery benefits and/or signal latency benefits. In some embodiments, the pitch of the conductive contacts 182 may be between 40 microns and 1 millimeter (e.g., between 40 microns and 50 microns, or between 100 microns and 1 millimeter). In embodiments in which the bridge component 110 includes conductive contacts 182 at its “bottom” face to couple to conductive contacts 180 at the bottom of the cavity 120 of the substrate 102, a dielectric material (e.g., a capillary underfill material) may support these connections; such a material is not shown in various ones of the accompanying drawings for clarity of illustration.

In some embodiments, a bridge component 110 may be included in a patch structure between the substrate 102 and the microelectronic components 130. For example, FIGS. 13-16 are side, cross-sectional views of example microelectronic assemblies 150 including patch structures 161, in accordance with various embodiments. The patch structure 161 may include the bridge component 110, which may have mold material 165 at its “top” face and/or its “bottom” face, and may be conductively coupled to the “top” face and the “bottom” face of the patch structure 161, as discussed further below. The patch structure 161 may also include stacks of conductive pillars 175, which may provide conductive pathways between the “top” face and the “bottom” face of the patch structure 161 such that the conductive contacts 118 of the bridge component 110 may be conductively coupled to the conductive contacts 134 of the microelectronic components 130 (via intervening solder 106 and other structures, discussed below). As illustrated in FIG. 13, in embodiments in which the bridge component 110 includes conductive contacts 182 at its “bottom” face, the conductive contacts 182 of the bridge component 110 may be conductively coupled to the conductive contacts 180 of the substrate 102 (via intervening solder 106 and other structures, discussed below). In particular, a stack of conductive pillars 175 may be coupled at the “top” face of the patch structure 161 to the conductive contacts 132 of the microelectronic components 130 via intervening solder 106 (and conductive vias 111 and conductive contacts 109, discussed below), and at the “bottom” face of the patch structure 161 to the conductive contacts 114 of the substrate 102 via intervening solder 106. The patch structure 161 and the microelectronic components 130 together may provide a microelectronic assembly 123 (which may be coupled to a substrate 102 to form the microelectronic assembly 150, as shown). Underfill material 147 may be disposed between the substrate 102 and the patch structure 161, as well as between the patch structure 161 and the microelectronic components 130; the underfill material 147 in these locations may have a same material composition, or different material compositions. A mold material 144 may be disposed between and around the microelectronic components 130. The underfill material 147 and the mold material 144 may have the same material composition, or different material compositions.

Various ones of the conductive pillars of the patch structure 161 may extend through a mold material 183, and the conductive pillars may include any suitable materials (e.g., copper and/or nickel). In some embodiments, the mold material 183 may include one or more organic resins and one or more types of filler particle. For example, the mold material 183 may include silica filler particles.

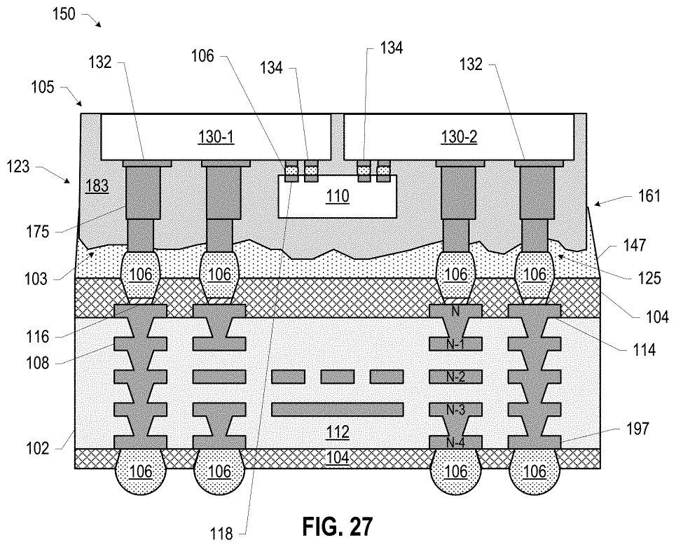

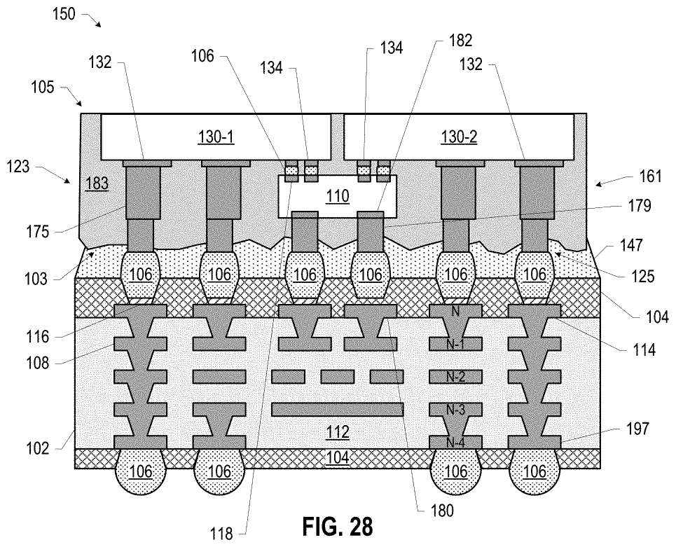

In the embodiment of FIGS. 13-16, the conductive pillars 175 may be arranged in decreasing diameter in the direction from the substrate 102 to the microelectronic components 130. In other embodiments (e.g., as discussed below with reference to FIGS. 27-28), the conductive pillars 175 may be arranged in increasing diameter in the direction from the substrate 102 to the microelectronic components 130. The conductive contacts 182 of the bridge component 110 may be coupled to conductive pillars 179 at the “bottom” face of the patch structure 161 by solder 106, and the conductive contacts 118 of the bridge component 110 may be in contact with conductive pillars 177 at the “top” face of the patch structure 161. The “bottommost” conductive pillars 175/179 of the patch structure 161 may serve as conductive contacts 125 for electrically coupling the patch structure 161 to the conductive contacts 114/180 of the substrate 102, as shown. Relative to previous approaches in which further passivation and lithographically patterned layers may be present between a bridge component 110 and a substrate 102, the microelectronic assemblies 150 of FIGS. 13-16 (and FIGS. 27-28, discussed below) may reduce manufacturing complexity, while the relatively “wide” conductive contacts 125 may potentially improve the maximum tolerable current flow from the substrate 102 (relative to embodiments in which current is routed through narrow vias). In any of the embodiments disclosed herein, a “stack” of conductive pillars 175 may include one conductive pillar 175, or more than two conductive pillars 175. The conductive contacts 182 of the bridge component 110 may be in contact with conductive pillars 179 at the “bottom” face of the patch structure 161, and the conductive contacts 118 of the bridge component 110 may be in contact with conductive pillars 177 at the “top” face of the patch structure 161. As shown in FIG. 13, the conductive pillars 179 of the patch structure 161 may be coupled to the conductive contacts 114 of the substrate 102 by intervening solder 106, and the conductive pillars 177 of the patch structure 161 may be coupled to the conductive contacts 134 of the microelectronic components 130 by intervening solder 106, conductive vias 111, and conductive contacts 109 (discussed below).

In some embodiments, a microelectronic assembly 150 including conductive pillars 175/177 may have a metallization region 113 between the conductive pillars 175/177 and the microelectronic components 130. For example, FIGS. 13-16 illustrate microelectronic assemblies 150 including conductive pillars 175/177 and a metallization region 113, in accordance with various embodiments. Individual stacks of conductive pillars 175/177 may be in contact with conductive vias 111 and conductive contacts 109 of the metallization region 113. The metallization region 113 may include a dielectric material 115, which may include any suitable material, such as a polyimide, polybenzoxazole, silicon nitride, or silicon oxide. The conductive contacts 109 may be conductively coupled to the conductive contacts 132/134 of the microelectronic components 130 by solder 106. Although the metallization regions 113 are depicted in FIGS. 13-16 (and others of the accompanying drawings) as having a single metallization layer, this is simply for ease of illustration, and a metallization region 113 may have one or more metallization layers including conductive vias and/or conductive lines arranged as desired into conductive pathways. Individual ones of the conductive vias 111 in the metallization region 113 may have a diameter that is smaller than a diameter of the conductive pillar 175/177 with which the conductive via 111 is in contact, as shown. In some embodiments, the metallization region 113 may serve to correct any lateral misalignment between the conductive vias 175/177 and the conductive contacts 132/134, respectively, that may arise during manufacturing. In some embodiments, a metallization region 113 may include one or more redistribution layers (RDLs) (e.g., instead of or in addition to the particular embodiments illustrated in the accompanying figures). In some embodiments, the metallization region 113 may be omitted from any of the patch structures 161 disclosed herein.

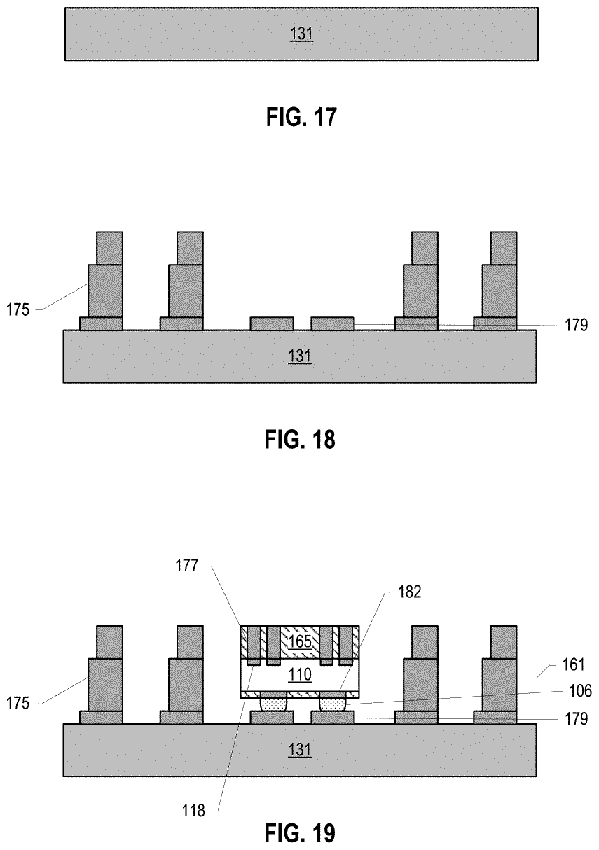

In the microelectronic assemblies 150 of FIGS. 13-16, the mold material 183 may have a “top” surface 105 (closer to the microelectronic components 130) and an opposing “bottom” surface 103 (closer to the substrate 102). The surface 103 may be recessed back from the bottom surfaces of the conductive contacts 125 such that the conductive contacts 125 are closer to the substrate 102 than the surface 103 is from the substrate 102. In some embodiments, the surface 103 may have a roughness that is greater than a roughness of the surface 105. Such a “rougher” surface 103 may be the result of manufacturing operations to recess the mold material 183 back from coplanarity with the conductive contacts 125; example manufacturing processes that include such operations are discussed below with reference to FIGS. 17-26.

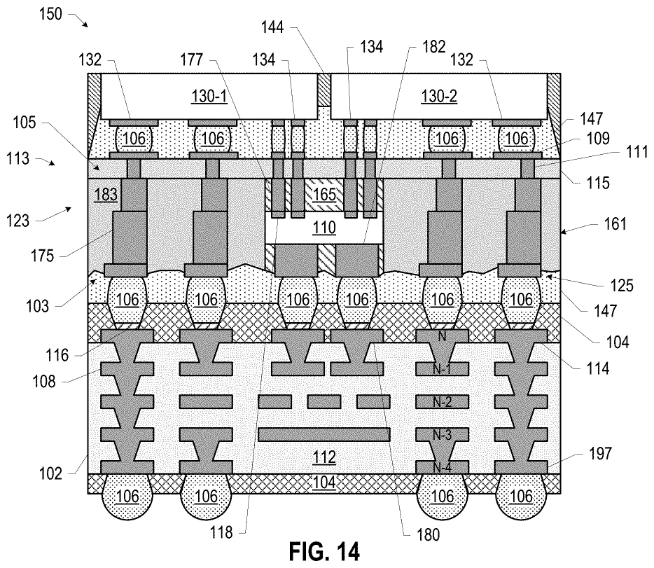

FIG. 13 illustrates an embodiment in which the conductive contacts 182 at the “bottom” face of the bridge component 110 are coupled to the conductive pillars 179 by intervening solder 106. In other embodiments, the conductive pillars 179 may be plated on or otherwise in direct contact with the conductive contacts 182. For example, FIG. 14 illustrates a microelectronic assembly 150 sharing many features with the microelectronic assembly 150 of FIG. 13, but having no solder 106 is between the conductive contacts 182 and the conductive pillars 179; instead, the conductive pillars 179 may be plated or otherwise formed on the conductive contacts 182 of the bridge component 110 before the bridge component 110 is assembled into the patch structure 161. As shown in FIG. 14, in some embodiments, the conductive pillars 179 may be surrounded by a mold material 165, which may have a same material composition as the mold material 183 or a different material composition.

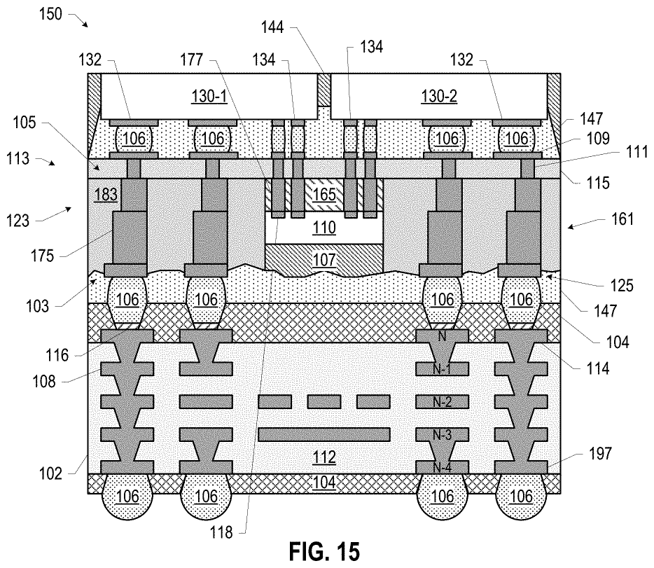

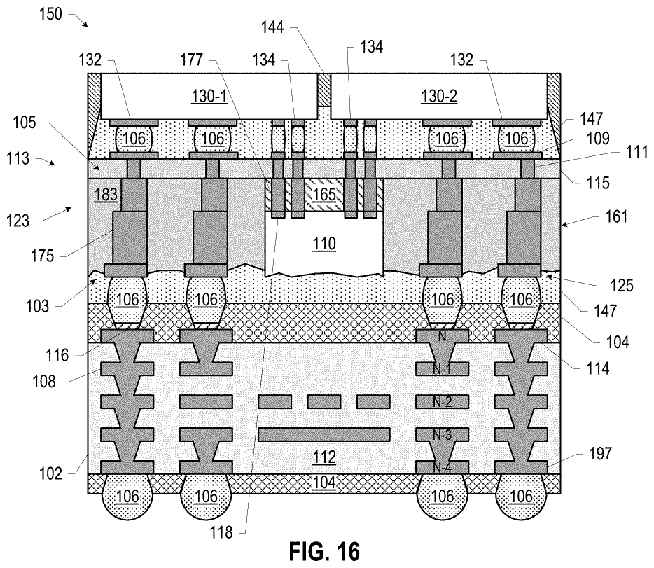

As discussed above with reference to FIGS. 13-14, a bridge component 110 may include conductive contacts 182 at its “bottom” face; in some such embodiments, the bridge component 110 may include through-substrate vias (TSVs, such as through-silicon vias) to electrically couple the conductive contacts 118 to the conductive contacts 182. In other embodiments, a bridge component 110 in a patch structure 161 may not include conductive contacts 182 at its “bottom” face. FIGS. 15-16 illustrate examples of microelectronic assemblies 150 sharing many features with the microelectronic assemblies 150 illustrated in FIGS. 13-14, but in which the bridge component 110 does not include conductive contacts 182.

In the particular embodiment of FIG. 15, a dielectric material 107 may be in contact with the “bottom” face of the bridge component 110, and the dielectric material 107 may itself provide a portion of the “bottom” surface of the patch structure 161 (along with the surface 103 of the mold material 183). In some embodiments, the dielectric material 107 may be a DAF. The dielectric material 107 may have any suitable dimensions; for example, in some embodiments, the dielectric material 107 may have a thickness between 5 microns and 10 microns. In some embodiments, the dielectric material 107 may have the same material composition as the mold material 183 (and thus the “bottom” surface of the dielectric material 107 may have a same roughness as the surface 103), while in other embodiments, the dielectric material 107 may have a different material composition than the mold material 183 (and thus the “bottom” surface of the dielectric material 107 may have a different roughness than the surface 103). In some embodiments, a dielectric material 107 may have a filler loading between 3 percent and 35 percent (e.g., when the dielectric material 107 is a DAF).

In the particular embodiment of FIG. 16, the “bottom” face of the bridge component 110 itself may provide a portion of the “bottom” surface of the patch structure 161 (along with the surface 103 of the mold material 183). In some embodiments, the “bottom” face of the bridge component 110 may be a semiconductor material, such as silicon. The “bottom” face of the bridge component 110 may have a different material composition than the mold material 183, and thus the “bottom” face of the bridge component 110 may have a different roughness than the surface 103.

The microelectronic assemblies 150 of FIGS. 13-16 may be manufactured using any suitable technique. For example, FIGS. 17-26 are side, cross-sectional views of various stages in an example process for the manufacture of the microelectronic assembly 150 of FIG. 13, in accordance with various embodiments. The microelectronic assemblies 150 of FIGS. 14-16 may be manufactured using similar processes, as discussed further below.

FIG. 17 illustrates an assembly including a carrier 131. In some embodiments, the carrier 131 may include glass or a semiconductor material (e.g., silicon) with a temporary bonding material (e.g., an adhesive) that can be separated from other structures formed thereon, as discussed further below. The assembly of FIG. 17 may be a portion of a “wafer-level” assembly in which multiple units like that illustrated in FIG. 17 are formed together, and then singulated at a later operation into “package-level” units (e.g., as discussed below with reference to FIG. 26).

FIG. 18 illustrates an assembly subsequent to forming conductive pillars 175 and 179 on the carrier 131 of the assembly of FIG. 17. In some embodiments, the conductive pillars 175 and 179 may be plated on to the carrier 131, with the number of plating operations depending upon the number of pillars in a stack (e.g., three operations to form the conductive pillars 175 of the assembly of FIG. 18). As shown in FIG. 45, the diameter of the conductive pillars 175 formed in subsequent plating operations may decrease relative to previous plating operations, resulting in the stacks of conductive pillars 175 with varying diameter as discussed above with reference to FIGS. 13-16. As the conductive pillars 175 are formed directly on the planar carrier 131, the bottom surfaces of the stacks of conductive pillars 175 (corresponding to the conductive contacts 125) may be highly coplanar, improving the quality of attachment between the patch structure 161 and the substrate 102 in later operations.

FIG. 19 illustrates an assembly subsequent to coupling the bridge component 110 to the assembly of FIG. 45. The bridge component 110 may have previously been augmented with conductive pillars 177 in contact with the conductive contacts 118 and extending through a mold material 165. When manufacturing the microelectronic assembly 150 of FIG. 14, the bridge component 110 may have previously been augmented with conductive pillars 179 in contact with the conductive contacts 182 and extending through the mold material 165. As shown in FIG. 19, the conductive contacts 182 may be coupled to the conductive pillars 179 by intervening solder 106.

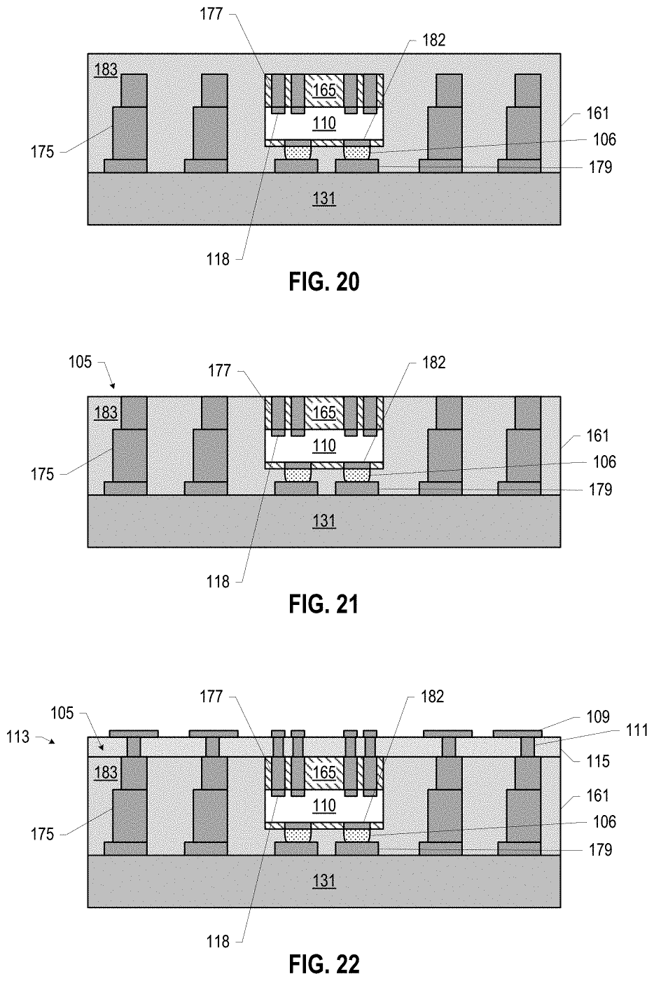

FIG. 20 illustrates an assembly subsequent to providing a mold material 183 on the carrier 131 and around the structures of the assembly of FIG. 19. Any suitable deposition technique may be used to provide the mold material 183.

FIG. 21 illustrates an assembly subsequent to grinding back or otherwise removing the overburden of the mold material 183 of the assembly of FIG. 20 to expose the conductive pillars 175 and the conductive pillars 177. The resulting exposed surface of the mold material 183 may be the surface 105, and the surface 105 may have a roughness that is a function of the material composition of the mold material 183 and the grinding technique used.

FIG. 22 illustrates an assembly subsequent to forming a metallization region 113 on the assembly of FIG. 21. As noted above, in some embodiments, the positions of the conductive vias 111 and the conductive contacts 109 may be selected to “correct” for any misalignment between the conductive pillars 175 and the conductive contacts 132 of the microelectronic components 130 and/or for any misalignment between the conductive pillars 177 and the conductive contacts 134 of the microelectronic components 130. As noted above, in some embodiments, no metallization region 113 may be included in a microelectronic assembly 150.

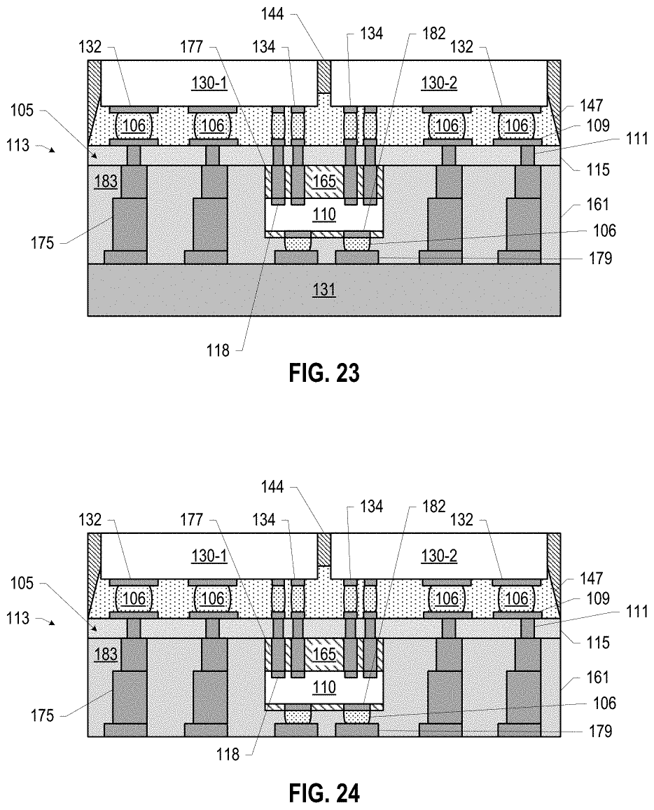

FIG. 23 illustrates an assembly subsequent to bonding the microelectronic components 130 to the conductive contacts 109 of the assembly of FIG. 22 via solder 106, providing an underfill material 147 between the patch structure 161 and the microelectronic components 130, and providing a mold material 144 (e.g., an over mold material) over the microelectronic components 130, as shown. In some embodiments, the overburden of mold material 144 may be polished back to expose the “top” faces of the microelectronic components 130.

FIG. 24 illustrates an assembly subsequent to removing the carrier 131 from the assembly of FIG. 23. Removing the carrier 131 may expose the conductive contacts 125 and the “bottom” surface of the mold material 183, as shown.

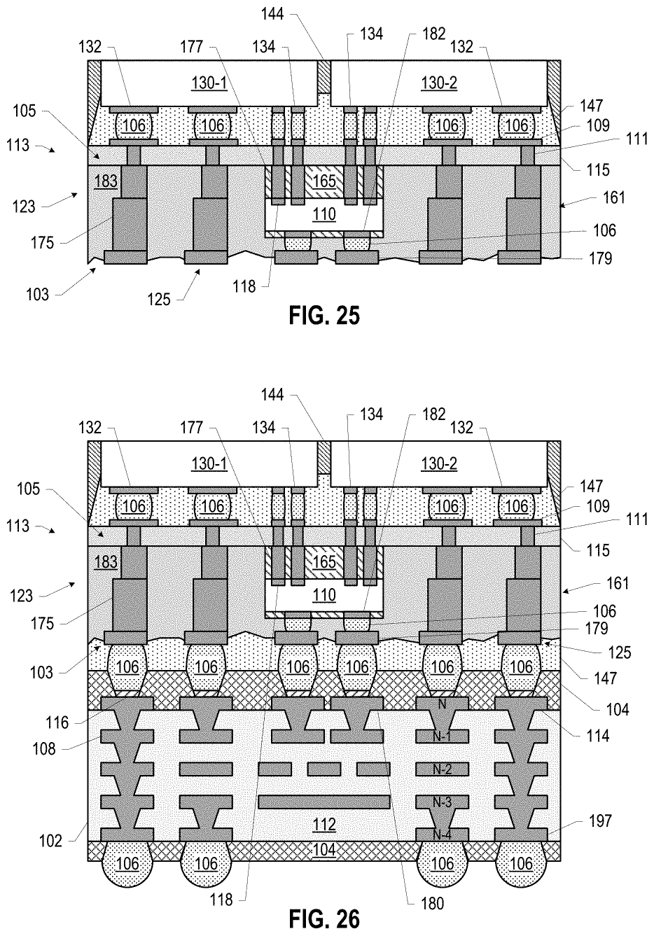

FIG. 25 illustrates an assembly subsequent to treating the assembly of FIG. 24 to recess the mold material 183, resulting in the “rough” surface 103. This treatment may result in the conductive contacts 125 protruding from the mold material 183, as shown. Any of a number of treatments may be applied. For example, in some embodiments, the assembly of FIG. 24 may be subject to an etch method that selectively etches polymer materials while etching metals (e.g., copper and/or nickel) little or not at all. Examples of such methods may include appropriate selective dry etches (e.g., an oxygen-based plasma etch technique or a reactive ion etch technique) and/or wet etches. In other embodiments, the assembly of FIG. 24 may be subject to a laser drilling or ablation technique to selectively remove some of the mold material 183 while largely leaving the conductive contacts 125 intact. As noted above, the surface 103 of the mold material 183 may be rougher than the surface 105, and the particular roughness of the surface 103 of the mold material 183 may depend upon a number of factors. For example, when an etch technique is used to recess the mold material 183, the roughness of the surface 103 may depend upon the etch selectivity between the resin materials in the mold material 183 and the filler particles in the mold material 183, and more generally, any of the materials present at the surface being etched (e.g., the dielectric material 107 of the embodiment of FIG. 15 and the exposed material of the bridge component 110 of the embodiment of FIG. 16). In some embodiments, an etch technique may etch resin materials at a higher rate than silica, and thus a surface 103 of a mold material 183 that has been etched would have a greater silica content than is present in the “bulk” mold material 183. Similarly, in embodiments in which a dielectric material 107 is etched, the exposed etched surface of the dielectric material 107 may have a greater silica content than is present in the “bulk” dielectric material 107. The assembly of FIG. 25 may be the microelectronic assembly 123.

FIG. 26 illustrates an assembly subsequent to bonding the conductive contacts 125 of the assembly of FIG. 25 to a substrate 102 via solder 106, and then providing underfill material 147 between the patch structure 161 and the substrate 102. The resulting assembly may take the form of the microelectronic assembly 150 of FIG. 13. In embodiments in which multiple ones of the microelectronic assemblies 150 of FIG. 13 are being manufactured simultaneously, the different microelectronic assemblies 150 may be singulated into “package-level” components as part of the operations of FIG. 26. The underfill material 147 between the microelectronic components 130 and the patch structure 161 may have the same material composition as, or a different material composition than, the underfill material 147 between the patch structure 161 and the substrate 102. The microelectronic assembly 150 of FIG. 15 may be manufactured using a process similar to that discussed with reference to FIGS. 17-26, but in which the bridge component 110 is coupled to the carrier 131 at the operations of FIG. 19 by the dielectric material 107 (e.g., a DAF) rather than solder 106. Similarly, the microelectronic assembly 150 of FIG. 16 may be manufactured using a process similar to that discussed with reference to FIGS. 17-26, but in which the bridge component 110 is placed on the carrier 131 at the operations of FIG. 19 rather than coupled by solder 106.

As noted above, a patch structure 161 may include conductive pillars 175 that are arranged in increasing diameter in the direction from the substrate 102 to the microelectronic components 130. For example, FIGS. 27-28 are side, cross-sectional views of example microelectronic assemblies 150 including stacks of conductive pillars 175 in contact with the conductive contacts 132 of the microelectronic components 130. In particular, a stack of one or more conductive pillars 175 may be in contact with each of the conductive contacts 132 of the microelectronic components 130, and the conductive pillars 175 may be conductively coupled to the conductive contacts 114 of the substrate 102 by solder 106. In the embodiments of FIGS. 39-40, the solder 106 in contact with the conductive pillars 175 may be closer to the substrate 102 than to the microelectronic components 130. The microelectronic assemblies 150 of FIGS. 27-28 share many features with the microelectronic assemblies 150 illustrated in preceding drawings, but as illustrated in FIGS. 27-28, an individual conductive pillar 175 in a stack may have a smaller diameter than another individual conductive pillar 175 in the stack that is farther from the substrate 102; a stack of conductive pillars 175 may thus have a “stepped” structure in which conductive pillars 175 closer to the substrate 102 are narrower than conductive pillars 175 farther from the substrate 102. The conductive pillars 175 may extend through a mold material 183, which may take the form of any of the mold materials 183 disclosed herein. As shown in FIGS. 27-28, the mold material 183 may also contact side faces of the microelectronic components 130, and may be disposed between the microelectronic components 130, as shown. As discussed above, the “bottom” surface 103 of the mold material 183 may be rougher than the “top” surface 105 of the mold material 183, and the surface 103 may be recessed back from the conductive contacts 125. In some embodiments, the surface 105 may be coplanar with the “top” surfaces of the microelectronic components 130, as shown in FIGS. 27-28.

In the embodiment of FIG. 27, the bridge component 110 may not include conductive contacts 182 at its “bottom” face, and mold material 183 may be disposed between the bridge component 110 and the substrate 102. In the embodiment of FIG. 28, the bridge component 110 may include conductive contacts 182 at its “bottom” face, and these conductive contacts 182 may be coupled to conductive contacts 114 of the substrate 102 by an intervening stack of one or more conductive pillars 179 (in contact with the conductive contacts 182 and extending through the mold material 183) and solder 106. An underfill material 147 may be disposed around the solder 106 coupling the conductive contacts 114 to the conductive pillars 175/179. In some embodiments, the underfill material 147 may contact side faces of the mold material 183. In some embodiments, the “bottom” surfaces of the “bottommost” conductive pillars 175/179 in a microelectronic assembly 150 may be coplanar, as shown.

The microelectronic assemblies 150 of FIGS. 27 and 28 may advantageously include a single mold material 183 securing the microelectronic components 130 and the bridge component 110, and may be manufactured using low-cost processes.

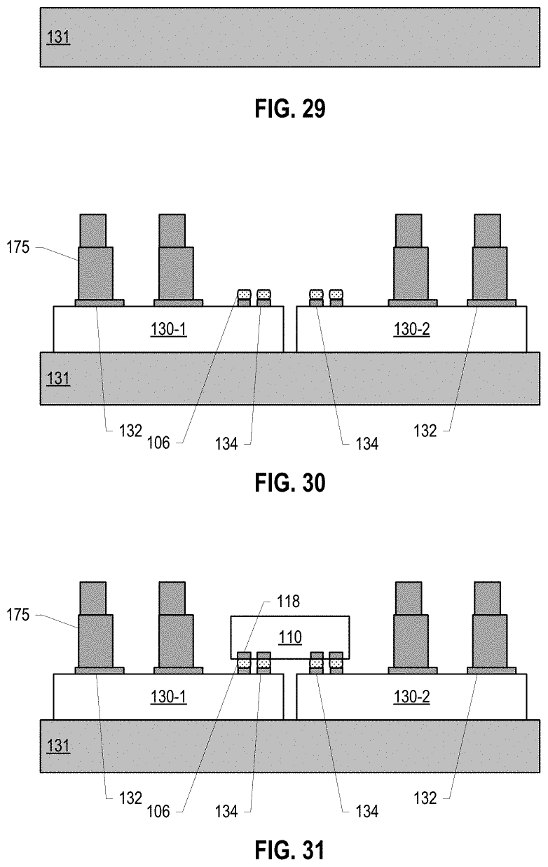

Microelectronic assemblies 150 like those illustrated in FIGS. 27-28 may be manufactured using any suitable techniques. FIGS. 29-33 are side, cross-sectional views of various stages in an example process for the manufacture of the microelectronic assembly 150 of FIG. 27, in accordance with various embodiments.

FIG. 29 illustrates an assembly including a carrier 131. The carrier 131 may take any suitable form (e.g., any of the forms discussed above with reference to FIG. 17). The assembly of FIG. 29 may be a portion of a “wafer-level” assembly in which multiple units like that illustrated in FIG. 29 are formed together, and then singulated at a later operation into “package-level” units (e.g., as discussed below with reference to FIG. 33).

FIG. 30 illustrates an assembly subsequent to placing the microelectronic components 130 on the carrier 131 of the assembly of FIG. 29, forming conductive pillars 175 on the conductive contacts 132 of the microelectronic components 130, and providing solder 106 on the conductive contacts 134 of the microelectronic components 130. In some embodiments, the conductive pillars 175 may be plated on to the conductive contacts 134, with the number of plating operations depending upon the number of conductive pillars 175 in a stack (e.g., two plating operations to form the conductive pillars 175 of the assembly of FIG. 30). As shown in FIG. 30, the diameter of the conductive pillars 175 formed in subsequent plating operations may decrease relative to previous plating operations.

FIG. 31 illustrates an assembly subsequent to coupling conductive contacts 118 of the bridge component 110 to the conductive contacts 134 of the microelectronic components 130 of the assembly of FIG. 30 via the solder 106. The coupling between the conductive contacts 118 and the conductive contacts 134 may be the tightest pitch interconnects that will be made in the microelectronic assembly 150, and forming them at this stage in manufacturing may allow the bridge component 110 to self-align or to otherwise achieve minimal misalignment with the microelectronic components 130.

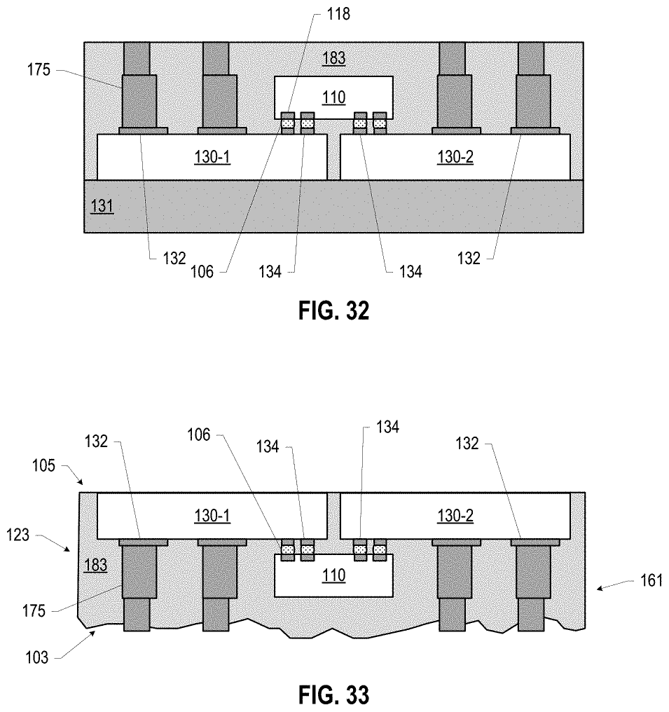

FIG. 32 illustrates an assembly subsequent to providing the mold material 183 around the microelectronic components 130 and the bridge component 110 of the assembly of FIG. 31, and then grinding or otherwise polishing back the overburden of the mold material 183 to form a planar exposed surface, as shown.

FIG. 33 illustrates an assembly subsequent to removing the carrier 131 from the assembly of FIG. 32, “flipping” the result, and then applying any of the treatments discussed above with reference to FIG. 25 to recess the mold material 183 relative to the conductive contacts 125. The conductive pillars 175 of the assembly of FIG. 33 may then be bonded to a substrate 102 via solder 106, and an underfill material 147 may be provided, to form the microelectronic assembly 150 of FIG. 39 (e.g., in accordance with the operations discussed above with reference to FIG. 26). In embodiments in which multiple ones of the microelectronic assemblies 150 of FIG. 27 are being manufactured simultaneously, the different microelectronic assemblies 150 may be singulated into “package-level” components as part of the operations of FIG. 33. The microelectronic assembly 150 of FIG. 28 may be manufactured using a process similar to that discussed with reference to FIGS. 29-33, but in which the conductive pillars 179 may be plated on the conductive contacts 182 of the bridge component 110 prior to bonding the bridge component 110 to the microelectronic components 130 (such conductive pillars 179 may be surrounded by a dielectric material, such as any of the mold materials disclosed herein, to provide mechanical support to the conductive pillars 179 during manufacturing), and in which the bonding operations discussed above with reference to FIG. 33 may also include bonding the conductive pillars 179 to the conductive contacts 180 of the substrate 102 by intervening solder 106.

In various ones of the manufacturing processes discussed with reference to FIGS. 17-26, the mold material 183 is deposited around the conductive pillars 175 so that the mold material 183 is in contact with the carrier 131. In other embodiments, a sacrificial material 127 may be formed around the conductive contacts 125 of the conductive pillars 175, and this sacrificial material 127 may then be treated instead of or in addition to the mold material 183. The sacrificial material 127 may include any suitable dielectric material, such as a DAF or a dry film resist. The sacrificial material 127 may include, for example, a polymer.

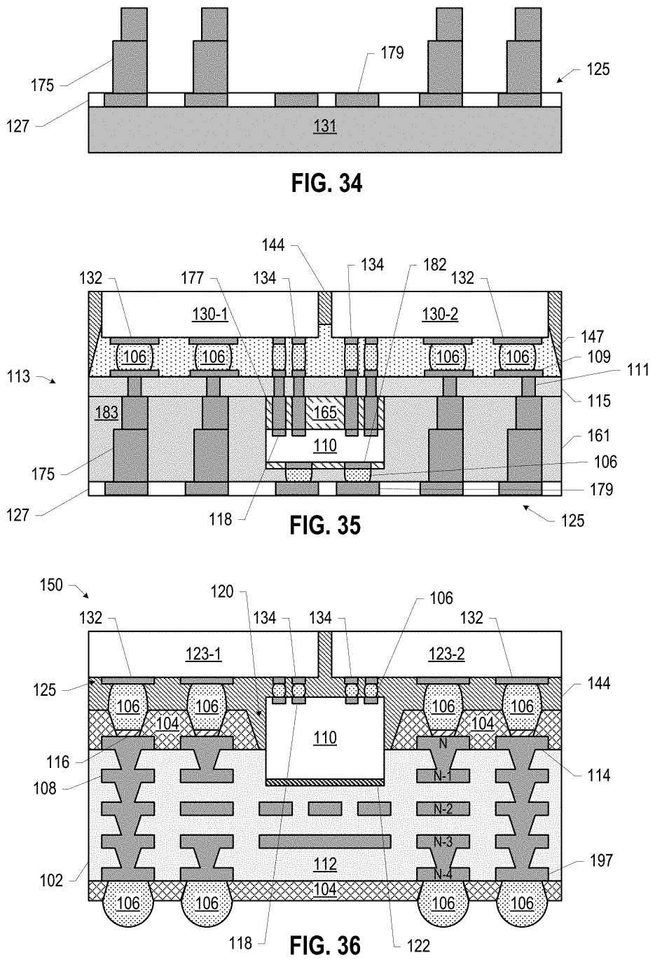

FIGS. 34 and 35 illustrate example stages in such a process. In particular, FIG. 34 illustrates an assembly subsequent to providing a sacrificial material 127 around the conductive pillars 175 and on the carrier 131 of FIG. 18. The sacrificial material 127 may be deposited by lamination after formation of the conductive contacts 125, and before plating of additional ones of the conductive pillars 175. The operations discussed above with reference to FIGS. 18-24 may then be performed on the assembly of FIG. 34, and then the carrier 131 may be removed, leaving the sacrificial material 127 in place in an assembly like that illustrated in FIG. 35. The treatment operations discussed above with reference to FIG. 25 may then be performed on the assembly of FIG. 35, removing some or all of the sacrificial material 127 instead of or in addition to removing some of the mold material 183. The sacrificial material 127 may be selected to achieve high etch selectivity relative to the conductive contacts 125, and thus a smooth surface with a uniform recessing from the conductive contacts 125 may be achieved. The operations of FIG. 26 may then be performed to form a microelectronic assembly 150. In such embodiments, the mold material 183 may include some or none of the sacrificial material 127 at its “bottom” surface 103, and thus the mold material 183 and the sacrificial material 127 together may provide a dielectric material with a rough “bottom” face; the exposed “bottom” face of the sacrificial material 127 (if present) or the “bottom” surface 103 of the mold material 183 may still be rougher than the surface 105.

In some embodiments, an adhesion promoter may be applied to the “bottom” surface of a patch structure 161 in a microelectronic assembly 123 before the microelectronic assembly 123 is bonded to a substrate 102 and an underfill material 147 is provided between the patch structure 161 and the substrate 102. In such embodiments, the adhesion promoter may help the underfill material 147 adhere to the patch structure 161. An adhesion promoter may include organic materials that are different from organic materials included in the mold material 183. Any of the microelectronic assemblies 150 disclosed herein may include such an adhesion promoter.

The amount by which the conductive contacts 125 may protrude from the mold material 183/other dielectric material may be controlled to achieve any desired result. For example, in some embodiments, a microelectronic assembly 150 may include a mold material 183/other dielectric material that is recessed back from the plane of the “bottom” surfaces of the conductive contacts 125 by a distance between 5 microns and 20 microns (e.g., between 10 microns and 15 microns).

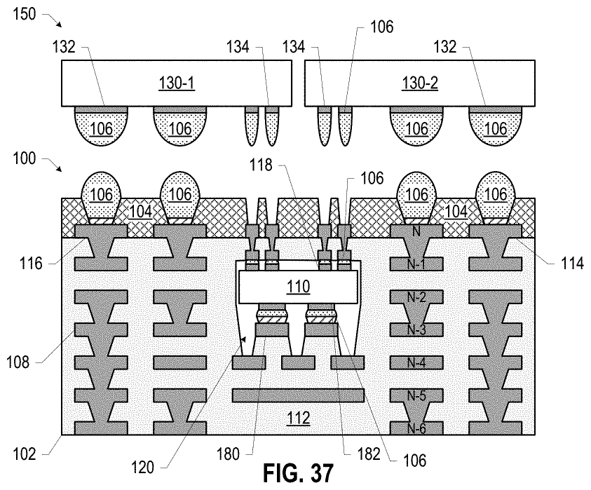

The microelectronic assemblies 123 disclosed herein may be included in microelectronic assemblies 150 having any desired structure. For example, FIG. 36 illustrates a microelectronic assembly 150 sharing many features with the microelectronic assembly 150 of FIG. 2, but in which microelectronic assemblies 123 (themselves including microelectronic components 130) take the place of the microelectronic components 130. More particularly, FIG. 36 illustrates a microelectronic assembly 150 in which multiple microelectronic assemblies 123 are coupled to a substrate 102 and communicatively coupled via a bridge component 110 in a recess of the substrate 102. In some embodiments, the bridge component 110 illustrated in FIG. 36 may include a semiconductor material (e.g., silicon) and may not include any TSVs. The microelectronic assemblies 123 of FIG. 36 may include any of the microelectronic assemblies 123 disclosed herein.

Although various ones of the embodiments disclosed herein have been illustrated for embodiments in which the conductive contacts 118 at the “top” face of the bridge component 110 are exposed in the microelectronic structure 100 (i.e., an “open cavity” arrangement), any suitable ones of the embodiments disclosed herein may be utilized in embodiments in which additional layers of the substrate 102 are built up over the bridge component 110, enclosing the bridge component 110 (i.e., an “embedded” arrangement). For example, FIG. 37 illustrates a microelectronic assembly 150 having a number of features in common with various ones of the embodiments disclosed herein, but in which additional dielectric material 112 and metal layers are disposed “above” the bridge component 110. As shown in FIG. 37, conductive pads and vias through this “additional” material may be used to allow microelectronic components 130 to conductively couple to the conductive contacts 118 via the intervening material of the substrate 102. Similarly, any suitable ones of the embodiments disclosed herein may be utilized in such an embedded arrangement.

The microelectronic structures 100 and microelectronic assemblies 150 disclosed herein may be included in any suitable electronic component. FIGS. 38-41 illustrate various examples of apparatuses that may include any of the microelectronic structures 100 and microelectronic assemblies 150 disclosed herein, or may be included in microelectronic structures 100 and microelectronic assemblies 150 disclosed herein, as appropriate.

FIG. 38 is a top view of a wafer 1500 and dies 1502 that may be included in any of the microelectronic structures 100 and microelectronic assemblies 150 disclosed herein. For example, a die 1502 may be included in a microelectronic structure 100/microelectronic assembly 150 as (or part of) a bridge component 110 and/or a microelectronic component 130. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 39, discussed below), one or more diodes, and/or supporting circuitry to route electrical signals to the transistors, as well as any other IC components. In some embodiments, a die 1502 may be a “passive” die in that it includes no active components (e.g., transistors), while in other embodiments, a die 1502 may be an “active” die in that it includes active components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 41) or other logic that is configured to store information in the memory devices or execute instructions stored in the memory array.

FIG. 39 is a side, cross-sectional view of an IC device 1600 that may be included in a microelectronic structure 100 and/or a microelectronic assembly 150. For example, an IC device 1600 may be included in a microelectronic structure 100/microelectronic assembly 150 as (or part of) a bridge component 110 and/or a microelectronic component 130. An IC device 1600 may be part of a die 1502 (e.g., as discussed above with reference to FIG. 38). One or more of the IC devices 1600 may be included in one or more dies 1502 (FIG. 38). The IC device 1600 may be formed on a substrate 1602 (e.g., the wafer 1500 of FIG. 38) and may be included in a die (e.g., the die 1502 of FIG. 38). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 38) or a wafer (e.g., the wafer 1500 of FIG. 38).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 39 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or I/O signals, may be routed to and/or from the devices (e.g., the transistors 1640) of the device layer 1604 through one or more interconnect layers disposed on the device layer 1604 (illustrated in FIG. 39 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600. In some embodiments, an IC device 1600 may be a “passive” device in that it includes no active components (e.g., transistors), while in other embodiments, a die 1502 may be an “active” die in that it includes active components.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 39). Although a particular number of interconnect layers 1606-1610 is depicted in FIG. 39, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 39. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 39. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a surface insulation material 1634 (e.g., polyimide or similar material) and one or more conductive contacts 1636 formed on the interconnect layers 1606-1610. In FIG. 39, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 40 is a side, cross-sectional view of an IC device assembly 1700 that may include one or more microelectronic structures 100 and/or microelectronic assemblies 150, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the microelectronic assemblies 150 discussed herein, or may otherwise include any of the microelectronic structures 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 40 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 40), male and female portions of a socket, an adhesive, an underfill material, and/or any other suitable electrical and/or mechanical coupling structure.

The package-on-interposer structure 1736 may include an IC package 1720 coupled to an package interposer 1704 by coupling components 1718. The coupling components 1718 may take any suitable form for the application, such as the forms discussed above with reference to the coupling components 1716. Although a single IC package 1720 is shown in FIG. 40, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 38), an IC device (e.g., the IC device 1600 of FIG. 39), or any other suitable component. Generally, the package interposer 1704 may spread a connection to a wider pitch or reroute a connection to a different connection. For example, the package interposer 1704 may couple the IC package 1720 (e.g., a die) to a set of ball grid array (BGA) conductive contacts of the coupling components 1716 for coupling to the circuit board 1702. In the embodiment illustrated in FIG. 40, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to TSVs 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more microelectronic structures 100 and/or microelectronic assemblies 150.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 40 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 41 is a block diagram of an example electrical device 1800 that may include one or more microelectronic structures 100 and/or microelectronic assemblies 150 in accordance with any of the embodiments disclosed herein. For example, any suitable ones of the components of the electrical device 1800 may include one or more of the microelectronic structures 100, microelectronic assemblies 150, IC device assemblies 1700, IC devices 1600, or dies 1502 disclosed herein. A number of components are illustrated in FIG. 41 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 41, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is a microelectronic assembly, including: a microelectronic component; a substrate; and a patch structure, wherein the patch structure is at least partially coupled between the microelectronic component and the substrate, the patch structure includes a bridge component in a mold material, the mold material is part of a dielectric material region, the dielectric material region has a first surface and an opposing second surface, the first surface is between the second surface and the substrate, and the first surface has a greater roughness than the second surface.

Example 2 includes the subject matter of Example 1, and further specifies that the patch structure includes a stack of conductive pillars.

Example 3 includes the subject matter of Example 2, and further specifies that diameters of the conductive pillars increase in a direction from the substrate to the microelectronic component.

Example 4 includes the subject matter of Example 2, and further specifies that diameters of the conductive pillars decrease in a direction from the substrate to the microelectronic component.

Example 5 includes the subject matter of any of Examples 1-4, and further specifies that the patch structure is coupled to the microelectronic component by first interconnects having a first pitch and by second interconnects having a second pitch, and the first pitch is less than the second pitch.

Example 6 includes the subject matter of Example 5, and further specifies that the first interconnects are in a volume between the bridge component and the microelectronic component.

Example 7 includes the subject matter of any of Examples 1-6, and further specifies that the patch structure has a first face and an opposing second face, the second face is between the first face and the microelectronic component, and the patch structure includes solder between the bridge component and the second face.

Example 8 includes the subject matter of any of Examples 1-7, and further includes: an underfill material between the microelectronic component and the patch structure.

Example 9 includes the subject matter of any of Examples 1-8, and further specifies that the microelectronic component is a first microelectronic component, the microelectronic assembly includes a second microelectronic component, and the patch structure is coupled between the second microelectronic component and the substrate.

Example 10 includes the subject matter of Example 9, and further specifies that the patch structure is coupled to the second microelectronic component by first interconnects having a first pitch and by second interconnects having a second pitch, and the first pitch is less than the second pitch.

Example 11 includes the subject matter of Example 10, and further specifies that the first interconnects are in a volume between the bridge component and the second microelectronic component.

Example 12 includes the subject matter of any of Examples 9-11, and further specifies that the mold material is between the first microelectronic component and the second microelectronic component.

Example 13 includes the subject matter of any of Examples 1-12, and further specifies that the patch structure includes a metallization region between the mold material and the microelectronic component.

Example 14 includes the subject matter of Example 13, and further specifies that the metallization region includes a dielectric material having a material composition that is different than a material composition of the mold material.

Example 15 includes the subject matter of any of Examples 1-12, and further specifies that the mold material contacts the microelectronic component.

Example 16 includes the subject matter of Example 15, and further specifies that the microelectronic component includes a first surface and an opposing second surface, the first surface of the microelectronic component is between the patch structure and the second surface of the microelectronic component, and the second surface of the dielectric material region is coplanar with the second surface of the microelectronic component.

Example 17 includes the subject matter of any of Examples 1-16, and further specifies that the patch structure is coupled to the substrate by interconnects.

Example 18 includes the subject matter of Example 17, and further specifies that at least some of the interconnects are in a volume between the bridge component and the substrate.

Example 19 includes the subject matter of any of Examples 1-18, and further specifies that the patch structure includes a dielectric material between the bridge component and the substrate, and the dielectric material has a material composition that is different than a material composition of the mold material.

Example 20 includes the subject matter of Example 19, and further specifies that the dielectric material includes a die attach film.

Example 21 includes the subject matter of any of Examples 19-20, and further includes: an underfill material between the patch structure and the substrate, wherein the underfill material has a different material composition than the dielectric material.

Example 22 includes the subject matter of any of Examples 1-21, and further specifies that the bridge component includes a first surface and a second surface opposite to the first surface, the first surface of the bridge component is between the substrate and the second surface of the bridge component, the patch structure includes a first surface and a second surface opposite to the first surface, the first surface of the patch structure is between the substrate and the second surface of the patch structure, and the first surface of the bridge component provides part of the first surface of the patch structure.

Example 23 includes the subject matter of Example 22, and further specifies that the first surface of the dielectric material region provides part of the first surface of the patch structure.

Example 24 includes the subject matter of any of Examples 22-23, and further includes: an underfill material between the first surface of the patch structure and the substrate, wherein the underfill material has a different material composition than the mold material.

Example 25 includes the subject matter of any of Examples 1-24, and further includes: an underfill material between the patch structure and the substrate, wherein the underfill material has a different material composition than the mold material.

Example 26 includes the subject matter of any of Examples 1-25, and further specifies that the bridge component includes through-semiconductor vias.

Example 27 includes the subject matter of any of Examples 1-25, and further specifies that the bridge component does not include through-semiconductor vias.

Example 28 includes the subject matter of any of Examples 1-27, and further specifies that the bridge component includes transistors.

Example 29 includes the subject matter of any of Examples 1-27, and further specifies that the bridge component does not include transistors.

Example 30 includes the subject matter of any of Examples 1-29, and further specifies that the substrate includes an organic dielectric material.

Example 31 includes the subject matter of any of Examples 1-30, and further specifies that the substrate is an interposer.

Example 32 includes the subject matter of any of Examples 1-31, and further specifies that the patch structure includes conductive contacts, the second surface of the dielectric material region is at least partially between the conductive contacts and the microelectronic component, and the first surface of the dielectric material region is recessed back from the conductive contacts.

Example 33 is a microelectronic assembly, including: a microelectronic component; a substrate; and a patch structure, wherein the patch structure is at least partially coupled between the microelectronic component and the substrate, the patch structure includes a mold material and a bridge component in the mold material, the mold material has a first face and an opposing second face, the second face is between the first face and the microelectronic component, the patch structure includes conductive pillars, a diameter of a conductive pillar proximate to the first face is less than a diameter of a conductive pillar proximate to the second face, the first face has a greater roughness than the second face, and the mold material contacts side faces of the microelectronic component.

Example 34 includes the subject matter of Example 33, and further specifies that the patch structure is coupled to the microelectronic component by first interconnects having a first pitch and by second interconnects having a second pitch, and the first pitch is less than the second pitch.

Example 35 includes the subject matter of Example 34, and further specifies that the first interconnects are in a volume between the bridge component and the microelectronic component.

Example 36 includes the subject matter of any of Examples 34-35, and further specifies that the first interconnects electrically couple the microelectronic component and the bridge component.

Example 37 includes the subject matter of any of Examples 33-36, and further specifies that the microelectronic component is a first microelectronic component, the microelectronic assembly includes a second microelectronic component, and the patch structure is coupled between the second microelectronic component and the substrate.

Example 38 includes the subject matter of Example 37, and further specifies that the patch structure is coupled to the second microelectronic component by first interconnects having a first pitch and by second interconnects having a second pitch, and the first pitch is less than the second pitch.

Example 39 includes the subject matter of Example 38, and further specifies that the first interconnects are in a volume between the bridge component and the second microelectronic component.

Example 40 includes the subject matter of any of Examples 38-39, and further specifies that the first interconnects electrically couple the microelectronic component and the bridge component.

Example 41 includes the subject matter of any of Examples 33-40, and further includes: an underfill material between the patch structure and the substrate, wherein the underfill material has a different material composition than the mold material.

Example 42 includes the subject matter of any of Examples 33-41, and further specifies that the bridge component includes through-semiconductor vias.

Example 43 includes the subject matter of any of Examples 33-41, and further specifies that the bridge component does not include through-semiconductor vias.

Example 44 includes the subject matter of any of Examples 33-43, and further specifies that the bridge component includes transistors.

Example 45 includes the subject matter of any of Examples 33-43, and further specifies that the bridge component does not include transistors.

Example 46 includes the subject matter of any of Examples 33-45, and further specifies that the substrate includes an organic dielectric material.

Example 47 is a microelectronic assembly, including: a first component, including a microelectronic component; and a patch structure, the patch structure includes a mold material that is part of a dielectric material region, the dielectric material region has a first surface and an opposing second surface, the second surface is between the first surface and the microelectronic component, and the first surface has a greater roughness than the second surface; a second component; a substrate, wherein the patch structure is at least partially coupled between the microelectronic component and the substrate, and a bridge component in a recess of the substrate, wherein the first component is coupled to the substrate and the bridge component, and the second component is coupled to the substrate and the bridge component.

Example 48 includes the subject matter of Example 47, and further specifies that the patch structure includes a stack of conductive pillars.

Example 49 includes the subject matter of Example 48, and further specifies that diameters of the conductive pillars increase in a direction from the substrate to the microelectronic component.

Example 50 includes the subject matter of Example 48, and further specifies that diameters of the conductive pillars decrease in a direction from the substrate to the microelectronic component.

Example 51 includes the subject matter of any of Examples 47-50, and further specifies that the patch structure is coupled to the microelectronic component by first interconnects having a first pitch and by second interconnects having a second pitch, and the first pitch is less than the second pitch.

Example 52 includes the subject matter of Example 51, and further specifies that the bridge component is a first bridge component, the patch structure includes a second bridge component embedded in the mold material, and the first interconnects are in a volume between the second bridge component and the microelectronic component.

Example 53 includes the subject matter of Example 52, and further specifies that the patch structure has a first face and an opposing second face, the second face is between the first face and the microelectronic component, and the patch structure includes solder between the second bridge component and the second face.

Example 54 includes the subject matter of any of Examples 47-53, and further specifies that the first component further includes an underfill material between the microelectronic component and the patch structure.

Example 55 includes the subject matter of any of Examples 47-54, and further specifies that the microelectronic component is a first microelectronic component, the first component includes a second microelectronic component, and the patch structure is coupled between the second microelectronic component and the substrate.

Example 56 includes the subject matter of Example 55, and further specifies that the patch structure is coupled to the second microelectronic component by first interconnects having a first pitch and by second interconnects having a second pitch, and the first pitch is less than the second pitch.

Example 57 includes the subject matter of any of Examples 52-56, and further specifies that the first interconnects are in a volume between the second bridge component and the second microelectronic component.

Example 58 includes the subject matter of any of Examples 52-57, and further specifies that the mold material is between the first microelectronic component and the second microelectronic component.

Example 59 includes the subject matter of any of Examples 47-58, and further specifies that the patch structure includes a metallization region between the mold material and the microelectronic component.

Example 60 includes the subject matter of Example 59, and further specifies that the metallization region includes a dielectric material having a material composition that is different than a material composition of the mold material.

Example 61 includes the subject matter of any of Examples 47-58, and further specifies that the mold material contacts the microelectronic component.

Example 62 includes the subject matter of Example 61, and further specifies that the microelectronic component includes a first surface and an opposing second surface, the first surface of the microelectronic component is between the patch structure and the second surface of the microelectronic component, and the second surface of the dielectric material region is coplanar with the second surface of the microelectronic component.

Example 63 includes the subject matter of any of Examples 47-62, and further specifies that the bridge component is a first bridge component, the patch structure includes a second bridge component embedded in the mold material, the patch structure includes a dielectric material between the second bridge component and the substrate, and the dielectric material has a material composition that is different than a material composition of the mold material.

Example 64 includes the subject matter of Example 63, and further specifies that the dielectric material includes a die attach film.

Example 65 includes the subject matter of any of Examples 63-64, and further includes: an underfill material between the patch structure and the substrate, wherein the underfill material has a different material composition than the dielectric material.

Example 66 includes the subject matter of any of Examples 47-65, and further specifies that the bridge component is a first bridge component, the patch structure includes a second bridge component embedded in the mold material, the second bridge component includes a first surface and a second surface opposite to the first surface, the first surface of the second bridge component is between the substrate and the second surface of the second bridge component, the patch structure includes a first surface and a second surface opposite to the first surface, the first surface of the patch structure is between the substrate and the second surface of the patch structure, and the first surface of the second bridge component provides part of the first surface of the patch structure.

Example 67 includes the subject matter of Example 66, and further specifies that the first surface of the dielectric material region provides part of the first surface of the patch structure.

Example 68 includes the subject matter of any of Examples 66-67, and further includes: an underfill material between the first surface of the patch structure and the substrate, wherein the underfill material has a different material composition than the mold material.

Example 69 includes the subject matter of any of Examples 47-68, and further includes: an underfill material between the patch structure and the substrate, wherein the underfill material has a different material composition than the mold material.

Example 70 includes the subject matter of any of Examples 47-69, and further specifies that the bridge component is a first bridge component, and the patch structure includes a second bridge component embedded in the mold material.

Example 71 includes the subject matter of any of Examples 47-70, and further specifies that the second bridge component includes through-semiconductor vias.

Example 72 includes the subject matter of any of Examples 47-70, and further specifies that the second bridge component does not include through-semiconductor vias.

Example 73 includes the subject matter of any of Examples 47-72, and further specifies that the second bridge component includes transistors.

Example 74 includes the subject matter of any of Examples 47-72, and further specifies that the second bridge component does not include transistors.

Example 75 includes the subject matter of any of Examples 47-74, and further specifies that the substrate includes an organic dielectric material.

Example 76 includes the subject matter of any of Examples 47-75, and further specifies that the bridge component includes through-semiconductor vias.

Example 77 includes the subject matter of any of Examples 47-75, and further specifies that the bridge component does not include through-semiconductor vias.

Example 78 includes the subject matter of any of Examples 47-77, and further specifies that the bridge component includes transistors.

Example 79 includes the subject matter of any of Examples 47-77, and further specifies that the bridge component does not include transistors.

Example 80 includes the subject matter of any of Examples 47-79, and further specifies that the second component includes a microelectronic component; and a patch structure, the patch structure includes a mold material that is part of a dielectric material region, the dielectric material region has a first surface and an opposing second surface, the second surface is between the first surface and the microelectronic component, and the first surface has a greater roughness than the second surface.

Example 81 is an electronic device, including: a circuit board; and a microelectronic assembly conductively coupled to the circuit board, wherein the microelectronic assembly includes any of the microelectronic assemblies of any of Examples 1-80.

Example 82 includes the subject matter of Example 81, and further specifies that the electronic device is a handheld computing device, a laptop computing device, a wearable computing device, or a server computing device.

Example 83 includes the subject matter of any of Examples 81-82, and further specifies that the circuit board is a motherboard.

Example 84 includes the subject matter of any of Examples 81-83, and further includes: a display communicatively coupled to the circuit board.

Example 85 includes the subject matter of Example 84, and further specifies that the display includes a touchscreen display.

Example 86 includes the subject matter of any of Examples 81-85, and further includes: a housing around the circuit board and the microelectronic assembly.

Example 87 is a method of manufacturing a microelectronic structure, including any of the methods disclosed herein.

Example 88 is a method of manufacturing a microelectronic assembly, including any of the methods disclosed herein.

1. A microelectronic assembly, comprising:
a microelectronic component;
a substrate; and
a patch structure, wherein the patch structure is at least partially coupled between the microelectronic component and the substrate, the patch structure includes a bridge component in a mold material, the mold material is part of a dielectric material region, the dielectric material region has a first surface and an opposing second surface, the first surface is between the second surface and the substrate, and the first surface has a greater roughness than the second surface.

2. The microelectronic assembly of claim 1, wherein the patch structure includes a stack of conductive pillars.

3. The microelectronic assembly of claim 2, wherein diameters of the conductive pillars increase in a direction from the substrate to the microelectronic component.

4. The microelectronic assembly of claim 2, wherein diameters of the conductive pillars decrease in a direction from the substrate to the microelectronic component.

5. The microelectronic assembly of claim 1, wherein the patch structure is coupled to the microelectronic component by first interconnects having a first pitch and by second interconnects having a second pitch, and the first pitch is less than the second pitch.

6. The microelectronic assembly of claim 1, wherein the patch structure has a first face and an opposing second face, the second face is between the first face and the microelectronic component, and the patch structure includes solder between the bridge component and the second face.

7. The microelectronic assembly of claim 1, wherein the patch structure includes conductive contacts, the second surface of the dielectric material region is at least partially between the conductive contacts and the microelectronic component, and the first surface of the dielectric material region is recessed back from the conductive contacts.

8. A microelectronic assembly, comprising:
a microelectronic component;
a substrate; and
a patch structure, wherein the patch structure is at least partially coupled between the microelectronic component and the substrate, the patch structure includes a mold material and a bridge component in the mold material, the mold material has a first face and an opposing second face, the second face is between the first face and the microelectronic component, the patch structure includes conductive pillars, a diameter of a conductive pillar proximate to the first face is less than a diameter of a conductive pillar proximate to the second face, the first face has a greater roughness than the second face, and the mold material contacts side faces of the microelectronic component.

9. The microelectronic assembly of claim 8, wherein the microelectronic component is a first microelectronic component, the microelectronic assembly includes a second microelectronic component, and the patch structure is coupled between the second microelectronic component and the substrate.

10. The microelectronic assembly of claim 8, further comprising:
an underfill material between the patch structure and the substrate, wherein the underfill material has a different material composition than the mold material.

11. The microelectronic assembly of claim 8, wherein the bridge component includes through-semiconductor vias.

12. The microelectronic assembly of claim 8, wherein the bridge component does not include through-semiconductor vias.

13. A microelectronic assembly, comprising:
a first component, including:
a microelectronic component; and
a patch structure, the patch structure includes a mold material that is part of a dielectric material region, the dielectric material region has a first surface and an opposing second surface, the second surface is between the first surface and the microelectronic component, and the first surface has a greater roughness than the second surface;
a second component;
a substrate, wherein the patch structure is at least partially coupled between the microelectronic component and the substrate, and
a bridge component in a recess of the substrate, wherein the first component is coupled to the substrate and the bridge component, and the second component is coupled to the substrate and the bridge component.

14. The microelectronic assembly of claim 13, wherein the patch structure includes a metallization region between the mold material and the microelectronic component.

15. The microelectronic assembly of claim 14, wherein the metallization region includes a dielectric material having a material composition that is different than a material composition of the mold material.

16. The microelectronic assembly of claim 13, wherein the mold material contacts the microelectronic component.

17. The microelectronic assembly of claim 16, wherein the microelectronic component includes a first surface and an opposing second surface, the first surface of the microelectronic component is between the patch structure and the second surface of the microelectronic component, and the second surface of the dielectric material region is coplanar with the second surface of the microelectronic component.

18. The microelectronic assembly of claim 13, wherein the bridge component is a first bridge component, the patch structure includes a second bridge component embedded in the mold material, the patch structure includes a dielectric material between the second bridge component and the substrate, and the dielectric material has a material composition that is different than a material composition of the mold material.

19. The microelectronic assembly of claim 18, wherein the dielectric material includes a die attach film.

20. The microelectronic assembly of claim 13, wherein the bridge component is a first bridge component, and the patch structure includes a second bridge component embedded in the mold material.
